(19) United States
(12) Patent Application Publication
(10) Pub. No.: US 2022/0112419 A1
(43) Pub. Date: Apr. 14, 2022

(54) THERMALLY CONDUCTIVE SHEET, ELECTRONIC DEVICE, AND ONBOARD DEVICE

(71) Applicant: Yazaki Corporation, Tokyo (JP)

(72) Inventors: Yumi YAMADA, Shizuoka (JP); Kenji OSADA, Shizuoka (JP); Kenichi KUSAYANAGI, Shizuoka (JP)

(73) Assignee: Yazaki Corporation, Tokyo (JP)

(21) Appl. No.: 17/498,929

(22) Filed: Oct. 12, 2021

(30) Foreign Application Priority Data
Oct. 14, 2020 (JP) 2020-173296

(51) Int. Cl. C09K 5/14; C08K 3/38; C08K 3/28; H05K 7/20

(52) U.S. Cl. CPC C09K 5/14; C08K 3/38; C08K 3/28; C08K 2003/282; C08K 2201/001; C08K 2201/014; C08K 2003/385; H05K 7/2039

(57) ABSTRACT

A thermally conductive sheet includes a resin composition including a silicone rubber, first thermally conductive fillers that are anisotropic, the first thermally conductive fillers being dispersed in the silicone rubber, and second thermally conductive fillers that are isotropic, the second thermally conductive fillers being dispersed in the silicone rubber. A content of the first thermally conductive fillers in the resin composition is 40% by mass or more and 75% by mass or less. A content of the second thermally conductive fillers in the resin composition is 10% by mass or more and 30% by mass or less. Major axes of the first thermally conductive fillers are oriented in a thickness direction of the thermally conductive sheet.

### CROSS-REFERENCE TO RELATED APPLICATIONS

The present application is based on, and claims priority from Japanese Patent Application No. 2020-173296, filed on Oct. 14, 2020, the entire contents of which are incorporated herein by reference.

### TECHNICAL FIELD

The present disclosure relates to a thermally conductive sheet, and an electronic device and an onboard device each using the same.

### BACKGROUND

Automobiles are equipped with various electronic devices, and these electronic devices may use heating elements such as power semiconductor devices. Since the heat emitted by the heating elements may cause the electronic devices to malfunction, heat is to be efficiently removed from the heating elements to prevent the heating elements from becoming too hot. Therefore, a thermally conductive sheet is disposed between the heating element and a heat-dissipating body such as a heat sink, and the heat of the heating element is transmitted to the heat-dissipating body through the thermally conductive sheet to cool the heating element.

Thermally conductive sheets are known to have thermally conductive fillers dispersed in resin. As a method of manufacturing such a thermally conductive sheet, JP2015-71287A discloses a method of fusing a resin sheet precursor including fillers oriented in the plane direction while folding it in a direction substantially perpendicular to the extrusion direction to orient the fillers in the thickness direction of the resin sheet.

### SUMMARY

When the thermally conductive fillers are oriented in the thickness direction of the resin sheet, a thermally conductive path is formed in the thickness direction, and heat can be efficiently taken from the heating element. However, when the resin sheet of JP2015-71287A is compressed at a certain compression ratio or higher in the thickness direction, internal structure of the resin sheet may be disturbed, and the thermal conductivity of the resin sheet may be lowered.

The present disclosure is made in view of the above issue. An object of the present disclosure is to provide a thermally conductive sheet having high thermal conductivity even when compressed in a thickness direction thereof, and an electronic device and an onboard device each using the thermally conductive sheet.

A thermally conductive sheet according to one aspect of the present disclosure includes a resin composition including: a silicone rubber; first thermally conductive fillers that are anisotropic, the first thermally conductive fillers being dispersed in the silicone rubber; and second thermally conductive fillers that are isotropic, the second thermally conductive fillers being dispersed in the silicone rubber. A content of the first thermally conductive fillers in the resin composition is 40% by mass or more and 75% by mass or less. A content of the second thermally conductive fillers in the resin composition is 10% by mass or more and 30% by mass or less. Major axes of the first thermally conductive fillers are oriented in a thickness direction of the thermally conductive sheet.

The present disclosure provides a thermally conductive sheet having high thermal conductivity even when compressed in a thickness direction thereof, and an electronic device and an onboard device each using the thermally conductive sheet.

### BRIEF DESCRIPTION OF THE DRAWINGS

FIG. 1 is a sectional view of an example of a thermally conductive sheet according to a present embodiment.

FIG. 2 is a graph illustrating a relationship between compressibility and thermal resistance of thermally conductive sheets according to examples and a comparative example.

### DETAILED DESCRIPTION

The following describes a thermally conductive sheet, an electronic device, and an onboard device according to the present embodiment in detail with reference to the drawings. Dimensional ratios in the drawings are exaggerated for explanation and may differ from the actual ratios.

[Thermally Conductive Sheet]

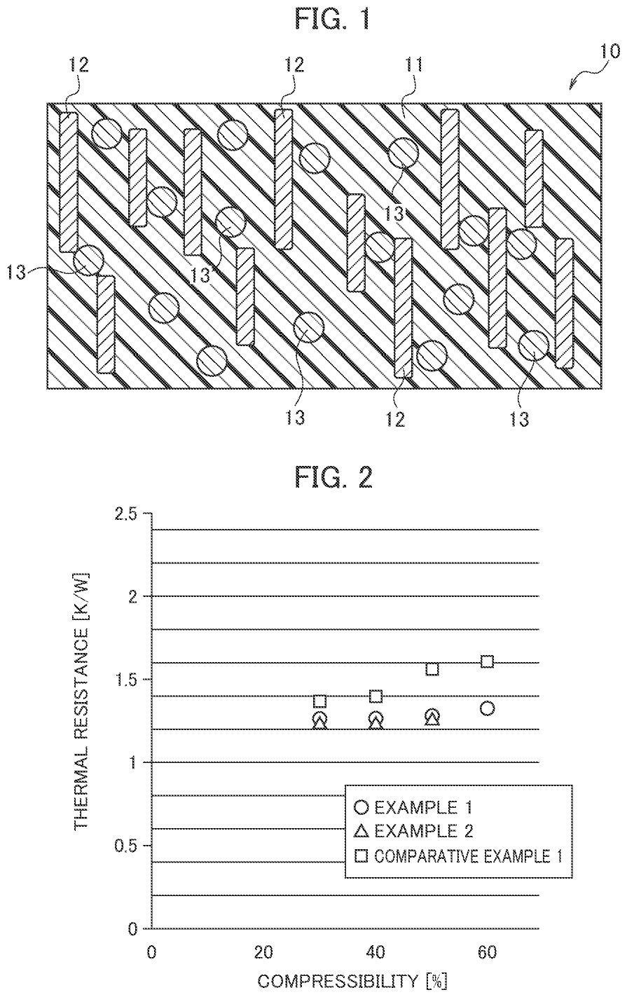

A thermally conductive sheet 10 according to the present embodiment includes a resin composition. As illustrated in FIG. 1, the resin composition includes a silicone rubber 11, first thermally conductive fillers 12 that are anisotropic, the first thermally conductive fillers 12 being dispersed in the silicone rubber 11, and second thermally conductive fillers 13 that are isotropic, the second thermally conductive fillers 13 being dispersed in the silicone rubber 11.

The silicone rubber 11 includes a cross-linked body obtained by cross-linking a silicone. The silicone rubber 11 has a high effect of absorbing physical vibrations and thus is usable in a place with many vibrations, such as a vehicle. The silicone is a polyorganosiloxane having a main chain composed of siloxane bonds. The silicone may include a homopolymer or copolymer of an organosiloxane, such as a dimethylsiloxane. The silicone may include at least one selected from the group consisting of a vinyl silicone, a phenyl silicone, and a fluorinated silicone.

The silicone rubber 11 may be a peroxide cross-linking type, an addition reaction cross-linking type, or a combination thereof. In the peroxide cross-linking type, for example, an organic peroxide is added to a silicone to generate free radicals, and the silicone is cross-linked to produce the silicone rubber 11. In the addition reaction cross-linking type, for example, a silicone having a vinyl group is cross-linked by hydrosilylation in the presence of a platinum catalyst to produce the silicone rubber 11.

The first thermally conductive fillers 12 are fillers having thermal conductivity and efficiently take heat from a heating element. Preferably, the thermal conductivity of the first thermally conductive fillers 12 is larger than that of the silicone rubber 11. Specifically, the thermal conductivity of the first thermally conductive fillers 12 is preferably 5 W/m·K or more, more preferably 10 W/m·K or more. The thermal conductivity of the first thermally conductive fillers 12 is preferably larger and has no upper limit, but may be, for example, 500 W/m·K or less, or 300 W/m·K or less. The thermal conductivity is obtained by calculating the product of a thermal diffusivity, a specific heat capacity, and a density. The thermal diffusivity is measured by a laser flash method in accordance with JIS R1611. The specific heat capacity is measured by a differential scanning calorimetry (DSC) method in accordance with JIS K7123-1987. The density is measured by an underwater displacement method in accordance with JIS K7112:1999.

The first thermally conductive fillers 12 may contain at least one of an inorganic substance or a metal. The inorganic substance may include, for example, at least one substance selected from the group consisting of a boron nitride, a carbon, an alumina, and an aluminum nitride. Preferably, the first thermally conductive fillers 12 include a boron nitride because of its excellent thermal conductivity and electrical insulation.

The first thermally conductive fillers 12 have anisotropy and each have, for example, a shape other than spherical or other than substantially spherical. Specifically, the first thermally conductive fillers 12 each have an aspect ratio of a major axis and a minor axis of a cross section passing through a center thereof, for example, 2 or more. The aspect ratio may be 5 or more, or 10 or more. The aspect ratio may be 100 or less, or 50 or less. The major axis is the longest part passing through the center of the first thermally conductive filler 12, and the minor axis is the shortest part passing through the center of the first thermally conductive filler 12. The first thermally conductive fillers 12 may each have, for example, at least one shape selected from the group consisting of a scale, a plate, a membrane, a cylinder, an ellipse, a flat, a spiral, a fiber, and a needle.

The first thermally conductive fillers 12 may be scaly, plate-like, film-like, cylindrical, elliptical, or flat fillers including a boron nitride, a graphite, a graphene, or the like. The first thermally conductive fillers 12 may be fibrous or needle-like fillers, such as a carbon, an alumina, an aluminum nitride, a metal, a boron nitride nanotube, or a carbon nanotube.

Preferably, the average particle diameter of the first thermally conductive fillers 12 is 20 μm or more and 100 μm or less. When the average particle diameter is 20 μm or more, the first thermally conductive fillers 12 dispersed in the silicone easily come into contact with each other in an oriented state to form a thermally conductive path, thereby improving the heat dissipation property of the thermally conductive sheet 10. When the average particle diameter is 100 μm or less, the thermally conductive sheet 10 having a stable shape is obtained. In the present specification, the average particle diameter is the average of the major axes of at least 10 or more inorganic particles measured using a microscope, such as a transmission electron microscope (TEM) or a scanning electron microscope (SEM).

The content of the first thermally conductive fillers 12 in the resin composition is 40% by mass or more and 75% by mass or less. When the content of the first thermally conductive fillers 12 is 40% by mass or more, the thermal conductivity of the thermally conductive sheet 10 is enhanced. When the content of the thermally conductive fillers 12 is 75% by mass or less, the thermally conductive sheet 10 having a stable shape is obtained. Preferably, the content of the first thermally conductive fillers 12 is 45% by mass or more. The content of the thermally conductive fillers 12 is preferably 70% by mass or less, more preferably 65% by mass or less.

The second thermally conductive fillers 13 are fillers having thermal conductivity, form a thermally conductive path in the thermally conductive sheet 10, and has a function of preventing turbulence of the internal structure in the thermally conductive sheet 10 against compression from a thickness direction of the thermally conductive sheet 10. Preferably, the thermal conductivity of the second thermally conductive fillers 13 is larger than that of the silicone rubber 11. Specifically, the thermal conductivity of the second thermally conductive fillers 13 is preferably 5 W/m·K or more, more preferably 10 W/m·K or more. The thermal conductivity of the second thermally conductive fillers 13 is preferably larger and has no upper limit, but may be, for example, 500 W/m·K or less, or 300 W/m·K or less. The thermal conductivity is obtained by calculating the product of a thermal diffusivity, a specific heat capacity, and a density in the same manner as described above.

The second thermally conductive fillers 13 may contain at least one of an inorganic substance or a metal. The inorganic substance may include, for example, at least one substance selected from the group consisting of an alumina, an aluminum nitride, a boron nitride, a carbon, such as a diamond, a magnesium oxide, and a titanium oxide. Preferably, the second thermally conductive fillers 13 include at least one of an alumina or an aluminum nitride because of its excellent thermal conductivity and electrical insulation.

Each of the second thermally conductive fillers 13 has isotropy and may have, for example, at least one selected from the group consisting of a spherical shape, a substantially spherical shape, and an indefinite shape. The second thermally conductive filler 13 may be an aggregate in which a plurality of thermally conductive fillers aggregates. The second thermally conductive filler 13 has an aspect ratio of a major axis and a minor axis of a cross section passing through a center thereof, for example, 1 or more and less than 2. The major axis is the longest part passing through the center of the second thermally conductive filler 13, and the minor axis is the shortest part passing through the center of the second thermally conductive filler 13.

The second thermally conductive filler 13 includes an inorganic material, such as an alumina, an aluminum nitride, a boron nitride, a carbon, such as a diamond, a magnesium oxide, or a titanium oxide, or a metal, each of which is a spherical, a substantially spherical, or an indefinite shape. Among these, preferably, the second thermally conductive filler 13 includes at least one thermally conductive filler selected from the group consisting of a spherical alumina, a spherical aluminum nitride, a substantially spherical alumina, and a substantially spherical aluminum nitride.

Preferably, the average particle diameter of the second thermally conductive fillers 13 is smaller than that of the first thermally conductive fillers 12. Making the average particle diameter of the second thermally conductive fillers 13 smaller than that of the first thermally conductive fillers 12 enables the second thermally conductive fillers 12 to be easily arranged among the first thermally conductive fillers 13.

Preferably, the average particle diameter of the second thermally conductive fillers 13 is 1 μm or more and 100 μm or less. When the average particle diameter is 1 μm or more, the second thermally conductive fillers 13 come into contact with the first thermally conductive fillers 12 and easily form a conductive path in the thermally conductive sheet 10. When the average particle diameter is 100 μm or less, the second thermally conductive fillers 13 are apt to exist among the first thermally conductive fillers 12, and the first thermally conductive fillers 12 and the second thermally conductive fillers 13 are apt to form a dense structure. The average particle diameter is preferably 3 μm or more, more preferably 5 μm or more. The average particle diameter is preferably 50 μm or less, more preferably 30 μm or less. The average particle diameter is the average of the major axes of at least 10 or more inorganic particles measured using a microscope, such as a transmission electron microscope (TEM) or a scanning electron microscope (SEM). The resin composition may include two or more second thermally conductive fillers 13 having different materials and average particle diameters.

The content of the second thermally conductive fillers 13 in the resin composition is 10% by mass or more and 30% by mass or less. Setting the content of the second thermally conductive fillers 13 within the above-described range prevents the decrease in the thermal conductivity of the thermally conductive sheet 10 even when the thermally conductive sheet 10 is compressed.

In addition to the silicone, the first thermally conductive fillers, and the second thermally conductive fillers, the resin composition may include a known additive, such as a reinforcing agent, a filler, a softening agent, a plasticizer, an anti-aging agent, an adhesive agent, an antistatic agent, and a kneaded adhesive.

The major axes of the first thermally conductive fillers 12 are oriented in the thickness direction of the thermally conductive sheet 10. This improves the thermal conductivity in the thickness direction of the thermally conductive sheet 10. Preferably, the thermal conductivity of the thermally conductive sheet 10 in the thickness direction is 8 W/m·K or more. Such a thermally conductive sheet 10 has high thermal conductivity from one surface to the other surface and thus efficiently removes heat from the heating element. The thermal conductivity is preferably larger and has no upper limit but is, for example, 100 W/m·K. The thermal conductivity is obtained by calculating the product of a thermal diffusivity, a specific heat capacity, and a density. The thermal diffusivity is measured by a laser flash method in accordance with JIS R1611. The specific heat capacity is measured by a differential scanning calorimetry (DSC) method in accordance with JIS K7123-1987. The density is measured by an underwater displacement method in accordance with JIS K7112:1999.

The thickness of the thermally conductive sheet 10 may be suitably varied according to the application but may be, for example, 0.1 mm to 10 mm. When the thickness of the thermally conductive sheet 10 is in such a range, heat dissipation is high, and handling is easy.

The thermally conductive sheet 10 according to the present embodiment includes the resin composition including the silicone rubber 11, the anisotropic first thermally conductive fillers 12 dispersed in the silicone rubber 11, and the isotropic second thermally conductive fillers 13 dispersed in the silicone rubber 11. The content of the first thermally conductive fillers 12 in the resin composition is 40% by mass or more and 75% by mass or less. The content of the second thermally conductive fillers 13 in the resin composition is 10% by mass or more and 30% by mass or less. The major axes of the thermally conductive fillers 12 are oriented in the thickness direction of the thermally conductive sheet 10.

The resin composition includes the first thermally conductive fillers 12 that are anisotropic, and the major axes direction of the first thermally conductive fillers 12 is oriented in the thickness direction of the thermally conductive sheet 10. Therefore, the thermally conductive sheet 10 has high thermal conductivity in the thickness direction. However, when the resin composition only includes the first thermally conductive fillers 12, if the thermally conductive sheet 10 is compressed in the thickness direction, the internal structure of the thermally conductive sheet 10 may be disturbed, and the thermal conductivity of the thermally conductive sheet 10 may be lowered.

The resin composition according to the present embodiment further includes second thermally conductive fillers 13 that are isotropic. The second thermally conductive fillers 13 are thus filled in gaps among the first thermally conductive fillers 12. Therefore, even when the thermally conductive sheet 10 is compressed in the thickness direction, the internal structure of the thermally conductive sheet 10 is not easily disturbed, and a state in which the major axes of the first thermally conductive fillers 12 are oriented in the thickness direction of the thermally conductive sheet 10 is easily maintained. Even when the orientation of the second thermally conductive fillers 13 is changed, since the second thermally conductive fillers 13 are interposed among the first thermally conductive fillers 12, the thermally conductive path in the thickness direction of the thermally conductive sheet 10 is hardly cut. Therefore, the thermally conductive sheet 10 has high thermal conductivity even when compressed in the thickness direction. As an example of the case where the thermally conductive sheet 10 is compressed in the thickness direction, the thermally conductive sheet 10 is compressed at a compressibility of, for example, 20% or more or 30% or more and 60% or less when the thermally conductive sheet 10 is sandwiched and bonded between the heating element and the heat-dissipating body.

[Electronic Device]

An electronic device according to the present embodiment includes the thermally conductive sheet 10. As described above, the thermally conductive sheet 10 has high thermal conductivity even when compressed in the thickness direction. Therefore, using the thermally conductive sheet 10 for the electronic device prevents malfunction due to heat generation by the electronic device. The electronic device may include a heating element and the thermally conductive sheet 10 covering the heating element. Covering the heating element with the thermally conductive sheet 10 takes heat from the heating element disposed on one surface of the thermally conductive sheet 10 and dissipates heat from a heat dissipation surface that is the other surface of the thermally conductive sheet 10. A heat-dissipating body, such as a heat sink, may be provided on the heat dissipation surface of the thermally conductive sheet 10. The heating element and the thermally conductive sheet 10 may be in direct contact with each other or may be in indirect contact via a layer, such as an adhesive. The thermally conductive sheet 10 and the heat-dissipating body may be in direct contact with each other or may be in indirect contact via a layer, such as an adhesive.

The heating element includes, for example, a power semiconductor element, and an IC (Integrated Circuit). Examples of the power semiconductor element include a diode, a thyristor, a gate turn-off thyristor, a MOSFET (Metal-Oxide-Semiconductor Field-Effect Transistor), and an IGBT (Insulated Gate Bipolar Transistor).

The silicone rubber 11 is used for the thermally conductive sheet 10 of the electronic device. Since the silicone rubber 11 easily absorbs vibration, the electronic device may be mounted on a vehicle. The electronic device is however not limited to an onboard device and may be a household electronic device.

[Onboard Device]

An onboard device according to the present embodiment includes the above-described electronic device, and a wire harness electrically connected to the electronic device. As described above, the electronic device effectively removes heat by the thermally conductive sheet 10. Therefore, the onboard device provided with the above-described electronic device reduces malfunction due to heat.

The wire harness may include a plurality of insulated wires, and a connector provided at the end of the plurality of insulated wires. The insulated wires may each include a metal conductor, and an insulating layer covering the metal conductor. The connector is provided to be electrically connectable to a mating connector, and by being connected to the mating connector, the connector is electrically connectable to an electronic device provided with the mating connector.

[Method of Manufacturing Thermally Conductive Sheet]

A method of manufacturing the thermally conductive sheet 10 includes a layered body forming step, a cross-linking step, and a slicing step.

(Layered Body Forming Process)

In the layered body forming step, a resin sheet is formed that has major axes of the first thermally conductive fillers 12 oriented in a plane direction. The resin sheet includes the resin composition including the silicone, the anisotropic first thermally conductive fillers 12 dispersed in the silicone, and the isotropic second thermally conductive fillers 13 dispersed in the silicone. The resin sheet may be formed by an extruder, for example. Raw materials such as silicone, first thermally conductive fillers 12, and second thermally conductive fillers 13 may be pre-mixed in a mixer and then indirectly fed into the extruder or may be fed directly into the extruder. The raw materials may be fed to the mixer or the extruder in one step at a time or may be fed to the mixer or the extruder separately in multiple steps. By adding and mixing the second thermally conductive fillers 13 in small amounts to a material to which a large amount of the first thermally conductive fillers 12 is added, more second thermally conductive fillers 13 are mixed and easily dispersed.

The mixer is not limited as long as the raw materials can be mixed. For example, a known mixer, such as a Banbury mixer, a kneader, or a roll mill, is usable. For the extruder, a known extruder, such as a single screw extruder, or a twin screw extruder, is usable. At an outlet of the extruder, for example, a T-die is provided, and by extruding the resin composition from the T-die into a sheet shape and taking up the sheet-like extruded product, major axes of the first thermally conductive fillers 12 are oriented in the extrusion direction (machine direction). That is, major axes of the first thermally conductive fillers 12 can be oriented in the plane direction of the resin sheet. The sheet-like extruded product may be cooled with a cooling roll or the like as necessary at the time of taking up.

In the present embodiment, an example of manufacturing the resin sheet using the extruder is described, but the present embodiment is not limited to this embodiment. For example, the resin sheet produced by mixing raw materials in a roll mill or the like may be used as the resin sheet having major axes of the first thermally conductive fillers 12 oriented in the plane direction.

The silicone can be obtained, for example, by dehydrating and condensing a silanol formed from an organohalosilane, such as a dimethyldichlorosilane. The silicone can also be obtained, for example, by ring-opening polymerization of a cyclic diorganosiloxane.

The first thermally conductive fillers 12 may be ones as described above. The content of the first thermally conductive fillers 12 in the resin composition is 40% by mass or more and 75% by mass or less. The first thermally conductive fillers 12 may be surface-treated with a surface treatment agent, such as a silane coupling agent or a surfactant, to improve the reactivity to the silicone. The first thermally conductive fillers 12 may be surface-treated prior to being added to the silicone or may be surface-treated by an integral blending process while being mixed with the silicone. However, to further improve the reactivity of the first thermally conductive fillers 12 to the silicone, preferably, the first thermally conductive fillers 12 are surface-treated before being added to the silicone.

The second thermally conductive fillers 13 may be ones as described above. The content of the second thermally conductive fillers 13 in the resin composition is 10% by mass or more and 30% by mass or less. The second thermally conductive fillers 13 may be surface-treated with a surface treatment agent, such as a silane coupling agent or a surfactant, to improve the reactivity to the silicone. The second thermally conductive fillers 13 may be surface-treated prior to being added to the silicone or may be surface-treated by an integral blending process while being mixed with the silicone. However, to further improve the reactivity of the second thermally conductive fillers 13 to the silicone, preferably, the second thermally conductive fillers 13 are surface-treated before being added to the silicone.

The raw materials may include a cross-linker, a plasticizer, such as a silicone oil, or an additive described above, such as a reinforcing agent. The cross-linker may include, for example, an organic peroxide. Adding an organic peroxide generates free radicals in the silicone in the cross-linking step described later. Examples of the organic peroxide used include a 2,5-dimethyl-2,5-bis(tert-butyl peroxy)hexane, a dicumyl peroxide, a di-tert-butyl peroxide, a 2,5-dimethyl-2,5-bis(tert-butyl peroxy)hexine-3, a 1,3-bis(tert-butyl peroxy isopropyl)benzene, a 1,1-bis(tert-butyl peroxy)-3,3,5-trimethylcyclohexane, an n-butyl-4,4-bis(tert-butyl peroxy)valerate, a benzoyl peroxide, a 2,4-dichlorobenzoyl peroxide, a tert-butyl peroxy benzoate, a tert-butyl peroxy isopropyl carbonate, a diacetyl peroxide, a lauroyl peroxide, and a tert-butyl cumyl peroxide. The organic peroxide may be used alone or in combination of two or more. Preferably, the amount of the organic peroxide added is 0.05 to 3 parts by mass per 100 parts by mass of the silicone.

Preferably, forming temperature in the extruder is lower than temperature at which the silicone is cross-linked by the cross-linker. The forming temperature is suitably changeable depending on the composition of the resin composition or the like, but it is for example, from 20° C. to 50° C.

While the thickness of the resin sheet is not limited, by adjusting the thickness of the sheet during extrusion, major axes of the first thermally conductive fillers 12 are oriented in the extrusion direction of the resin sheet. Specifically, by setting the sheet thickness in a range of, for example, 0.1 to 5 mm, the major axes of the first thermally conductive fillers 12 are oriented in the extrusion direction of the sheet.

The thickness of the resin sheet is not limited but is preferably 0.1 mm or more, more preferably 0.3 mm or more from the viewpoint of production speed. The thickness of the resin sheet is preferably 5 mm or less, more preferably 2 mm or less from the viewpoint of ease of production.

(Layered Body Forming Process)

In the layered body forming step, the resin sheet is layered so that the major axes of the first thermally conductive fillers 12 are in the same direction. The method of layering the resin sheet is not limited, and it is only required that the resin sheet is layered in such a manner that the first thermally conductive fillers 12 have their major axes in the same direction. For example, a plurality of resin sheets may be layered one by one, or a rolled resin sheet may be folded and layered.

(Cross-Linking Process)

In the cross-linking step, the silicone in the layered body is cross-linked to form the layered body cross-linked. The silicones in the layered body are cross-linked to each other by cross-linking, and thus the silicone rubber 11 excellent in physical characteristics is produced. In the cross-linking, the silicones in the resin sheet are cross-linked, and the silicones between layered parts of the resin sheet are cross-linked.

The heating temperature of the silicone is, for example, 120 to 190° C., depending on types of silicone and cross-linker used as raw materials. The heating time of the silicone is, for example, 5 to 20 minutes, depending on types of silicone and cross-linker used as raw materials. The layered body may be heated under pressure, and the pressure for pressurizing the layered body is, for example, 5 to 15 kPa. The layered body may be heated under pressure by an electric heat press machine, for example, to cross-link the silicone in the layered body to form a cross-linked layered body.

(Slicing Step)

In the slicing step, the layered body cross-linked may be sliced perpendicular to a direction in which the major axes of the first thermally conductive fillers 12 are oriented. Thus, slicing the layered body in this manner provides the thermally conductive sheet 10 having a desired thickness and in which major axes of the first thermally conductive fillers 12 are oriented in the thickness direction. When the layered body before slicing has a desired thickness, the slicing step is not necessary, and the layered body may be used as the thermally conductive sheet 10 in an electronic device or the like.

In the method of manufacturing the thermally conductive sheet 10 according to the present embodiment, the thermally conductive sheet 10 having high thermal conductivity even when compressed in the thickness direction as described above is manufactured.

### EXAMPLES

The present embodiment is described in more detail below with reference to examples and a comparative example. However, the present embodiment is not limited to these examples.

The following materials were sufficiently kneaded in the ratios in Table 1, and resin sheets having a thickness of 1 mm in which major axes of the first thermally conductive fillers 12 were oriented in the plane direction (extrusion direction) were manufactured by a single screw extruder.

Silicone: Dow, SILASTIC (registered trademark) DY32-1005U Cross-linker A: 2,5-dimethyl-2,5-bis(tert-butylperoxy)hexane, Dow, SILASTIC (registered trademark) RC-4 50P

Cross-linker B: Dow, SILASTIC (registered trademark) MR-53 Plasticizer: Silicone oil, Shin-Etsu Chemical Co., Ltd., Shin-Etsu Silicone (registered trademark) KF9600-3000cs

First thermally conductive fillers: Anisotropic boron nitride (BN), Momentive, PolarTherm (registered trademark) PT110, Average particle diameter 45 μm

Second thermally conductive fillers (5 μm): Isotropic aluminum nitride, Tokuyama Corporation, HF-05, Average particle diameter 5 μm

Second thermally conductive fillers (30 μm): Isotropic aluminum nitride FURUKAWA DENSHI CO., LTD., FAN-f30-A1, Average particle diameter 30 μm

Fifteen resin sheets were layered so that the major axes of the first thermally conductive fillers were in the same direction and placed in a mold having a thickness of 10 mm. A layered body of resin sheets installed in the mold was heated at a temperature of 170° C. and a pressure of 10 kPa for 10 minutes, and the silicone in the layered body was cross-linked to form a cross-linked layered body. Then, the cross-linked layered body was taken out of the mold, and the layered body was sliced to a thickness of 1 mm perpendicular to the direction in which the major axes of the first thermally conductive fillers were oriented by a razor attached to a hand press machine. In this way, the thermally conductive sheet having a thickness of 1 mm was obtained.

TABLE 1

| | | | Comparative |
|---|---|---|---|
| | Example 1 | Example 2 | Example 1 |
| Silicone (parts by mass) | 100 | 100 | 100 |
| Cross-linker 1 (parts by mass) | 1.75 | 1.75 | 1.75 |
| Cross-linker 2 (parts by mass) | 0.75 | 0.75 | 0.75 |
| Plasticizer (parts by mass) | 200 | 200 | 200 |
| First thermally conductive | 700 | 700 | 700 |
| filers (parts by mass) | | | |
| Second thermally conductive | 130 | — | — |
| filers (5 μm) (parts by mass) | | | |
| Second thermally conductive | — | 420 | — |
| filers (30 μm) (parts by mass) | | | |
| Total amount (parts by mass) | 1132.5 | 1422.5 | 1002.5 |
| First thermally conductive | 61.8 | 49.2 | 69.8 |
| filers (% by mass) | | | |
| Second thermally conductive | 11.5 | 29.5 | — |
| filers (% by mass) | | | |

[Evaluation]

(Thermal Resistance)

The thermally conductive sheets with the thickness of 1 mm were compressed by 0.3 mm, 0.4 mm, 0.5 mm, and 0.6 mm. The compressibility of the thermally conductive sheets compressed as described above was set to 30%, 40%, 50%, and 60%, respectively, and the thermal resistance of these thermally conductive sheets was measured according to ASTM D5470 using a thermal conductivity measuring device (DynTIM Tester) of Siemens K.K. These results are illustrated in FIG. 2.

As illustrated in FIG. 2, the thermally conductive sheets of example 1 and example 2 did not show a large increase in the thermal resistance value and did not have a large decrease in the thermal conductivity confirmed when the compressibility increased, compared with the thermally conductive sheet of comparative example 1. From these results, it is considered that the decrease in the thermal conductivity of the thermally conductive sheet is prevented because the second thermally conductive fillers prevent the orientation of the first thermally conductive fillers from being disturbed by the compression of the thermally conductive sheet.

The present embodiment has been described above. The present embodiment is however not limited thereto, and various modifications can be made within the scope of the gist of the present embodiment.

What is claimed is:

1. A thermally conductive sheet, comprising:
a resin composition comprising: a silicone rubber; first thermally conductive fillers that are anisotropic, the first thermally conductive fillers being dispersed in the silicone rubber; and second thermally conductive fillers that are isotropic, the second thermally conductive fillers being dispersed in the silicone rubber, wherein
a content of the first thermally conductive fillers in the resin composition is 40% by mass or more and 75% by mass or less,
a content of the second thermally conductive fillers in the resin composition is 10% by mass or more and 30% by mass or less, and
major axes of the first thermally conductive fillers are oriented in a thickness direction of the thermally conductive sheet.

2. The thermally conductive sheet according to claim 1, wherein the second thermally conductive fillers have an average particle diameter smaller than that of the first thermally conductive fillers.

3. The thermally conductive sheet according to claim 1, wherein the first thermally conductive fillers comprise a boron nitride.

4. The thermally conductive sheet according to claim 1, wherein the second thermally conductive fillers comprise at least one of an alumina or an aluminum nitride.

5. An electronic device, comprising
the thermally conductive sheet according to claim 1.

6. An onboard device, comprising:
the electronic device according to claim 5; and
a wire harness electrically connected to the electronic device.
